(19) United States
(12) Patent Application Publication
(10) Pub. No.: US 2026/0146199 A1
(43) Pub. Date: May 28, 2026

(54) METHOD FOR PROCESSING SEMICONDUCTOR SUBSTRATE, METHOD FOR MANUFACTURING SEMICONDUCTOR DEVICE, AND PROCESSING SOLUTION FOR SEMICONDUCTOR DEVICE

(71) Applicant: TOKYO OHKA KOGYO CO., LTD., Kanagawa (JP)

(72) Inventor: Kenji SEKI, Kanagawa (JP)

(21) Appl. No.: 19/392,380

(22) Filed: Nov. 18, 2025

Related U.S. Application Data
(60) Provisional application No. 63/723,746, filed on Nov. 22, 2024.

(51) Int. Cl. H01L 21/02; C09K 13/06

(52) U.S. Cl. CPC C09K 13/06

(57) ABSTRACT

Provided are a method for processing a semiconductor substrate, a method for manufacturing a semiconductor device, and a processing solution for a semiconductor device usable therefor, in which: a processing step of processing a semiconductor substrate including a layer containing a metal nitride with a processing solution for a semiconductor device is included; the processing solution for a semiconductor device contains NH₃, a corrosion inhibitor, and water; the corrosion inhibitor is at least one selected from the group consisting of 5-methyl-1H-benzotriazole, imidazole, and 5-amino-1H-tetrazole; and a mass ratio of a content of NH₃ to a content of the corrosion inhibitor (NH₃/corrosion inhibitor) is 5 to 60.

### CROSS-REFERENCE TO RELATED APPLICATIONS

This application claims priority to U.S. Provisional Application No. 63/723,746, filed with the United States Patent and Trademark Office on Nov. 22, 2024, which is incorporated herein by reference in its entirety.

The present invention relates to a method for processing a semiconductor substrate, a method for manufacturing a semiconductor device, and a processing solution for a semiconductor device.

### BACKGROUND OF THE INVENTION

### 1. Technical Field

### 2. Description of the Related Art

In a wiring forming process of a semiconductor device, for example, a method is adopted in which a hard mask layer (HM layer) is formed on a substrate on which a metal wiring layer, a silicon-based interlayer insulating film, or the like is laminated, and then etching is performed. Then, the substrate is etched using the patterned HM layer as a mask layer to form a wiring pattern or the like of metal wiring or the like.

In such wiring formation processing of a semiconductor device, miniaturization of metal wiring is required, and metal such as copper is used as a material of the metal wiring from the viewpoint of meeting such a requirement. A metal nitride film such as a tantalum nitride (TaN) film (tantalum nitride film) is used as a film that can function as a barrier film while ensuring adhesion to copper wiring or the like.

On the other hand, as the processing solution for etching use described above, for example, a processing solution containing an acidic component such as hydrogen peroxide and an alkali component such as NH₃ or tetramethylammonium hydroxide (TMAH) is used. Some processing solutions having such a composition are used for the purpose of removing the above-described metal nitride film such as tantalum nitride and protecting the above-described metal wiring such as copper.

Regarding the composition of such a processing solution for etching use, for example, Patent document 1 (JP 2017-216444 A) discloses an etching solution containing (A) oxalic acid, (B) polyvinylpyrrolidone, and (C) water.
Patent Document 1: JP 2017-216444 A

### SUMMARY OF THE INVENTION

However, the conventional processing solution for etching use is insufficient for achieving both the removability of a metal nitride such as tantalum nitride and the anticorrosion property of a metal layer containing metal atoms such as copper atoms, and thus there is room for improvement.

For example, even in the case of a processing solution which can ensure the removability of a metal nitride to some extent and can etch a layer containing the metal nitride (e.g., a metal nitride film or the like) to some extent, there is a problem that the anticorrosion property of the metal layer is insufficient because the damage suppression of the metal layer containing metal atoms such as copper atoms is insufficient. Conversely, even a processing solution capable of reducing damage of a metal layer containing metal atoms such as copper atoms to some extent has a problem that the removability of a metal nitride is insufficient.

The present invention has been made in view of the above circumstances, and an object of the present invention is to provide a method for processing a semiconductor substrate, a method for manufacturing a semiconductor device, and a processing solution for a semiconductor device, which are excellent in the removability of a metal nitride and the anticorrosion property of a metal layer.

As a result of intensive studies to achieve the object described above, the present inventors have found that a method for processing a semiconductor substrate includes a processing step of processing a semiconductor substrate including a layer containing a metal nitride with a processing solution for a semiconductor device, the processing solution for a semiconductor device containing NH₃, a corrosion inhibitor, and water, the corrosion inhibitor being at least one selected from the group consisting of 5-methyl-1H-benzotriazole, imidazole, and 5-amino-1H-tetrazole, and a mass ratio of a content of NH₃ to a content of the corrosion inhibitor (NH₃/corrosion inhibitor) is 5 to 60, and thus have completed the present invention.

That is, the present invention is as follows.

<1>

A method for processing a semiconductor substrate including a processing step of processing a semiconductor substrate including a layer containing a metal nitride with a processing solution for a semiconductor device, in which: the processing solution for a semiconductor device contains NH₃, a corrosion inhibitor, and water; the corrosion inhibitor is at least one selected from the group consisting of 5-methyl-1H-benzotriazole, imidazole, and 5-amino-1H-tetrazole; and a mass ratio of a content of the NH₃ to a content of the corrosion inhibitor (NH₃/corrosion inhibitor) is 5 to 60.

<2>

The method for processing a semiconductor substrate according to <1>, in which the processing solution for a semiconductor device further contains hydrogen peroxide.

<3>

The method for processing a semiconductor substrate according to <1> or <2>, in which the processing solution for a semiconductor device further contains a surfactant.

<4>

The method for processing a semiconductor substrate according to any one of <1> to <3>, in which the processing solution for a semiconductor device further contains a chelating agent.

<5>

The method for processing a semiconductor substrate according to <2>, further including, before the processing step, a preparation step of preparing the processing solution for a semiconductor device by mixing a first chemical solution containing the NH₃, the corrosion inhibitor, and the water with a second chemical solution containing the hydrogen peroxide.

<6>

A method for manufacturing a semiconductor device including a step of preparing a semiconductor substrate including a layer containing a metal nitride subjected to etching, and a processing step of processing the semiconductor substrate subjected to the etching with a processing solution for a semiconductor device, in which: the processing solution for a semiconductor device contains NH₃, a corrosion inhibitor, and water; the corrosion inhibitor is at least one selected from the group consisting of 5-methyl-1H-benzotriazole, imidazole, and 5-amino-1H-tetrazole; and a mass ratio of a content of the NH₃ to a content of the corrosion inhibitor (NH₃/corrosion inhibitor) is 5 to 60.

<7>

The method for manufacturing a semiconductor device according to <6>, in which the processing solution for a semiconductor device further contains hydrogen peroxide.

<8>

The method for manufacturing a semiconductor device according to <6> or <7>, in which the processing solution for a semiconductor device further contains a surfactant.

<9>

The method for manufacturing a semiconductor device according to any one of <6> to <8>, in which the processing solution for a semiconductor device further contains a chelating agent.

<10>

The method for manufacturing a semiconductor device according to <7>, further including, before the processing step, a preparation step of preparing the processing solution for a semiconductor device by mixing a first chemical solution containing the NH₃, the corrosion inhibitor, and the water with a second chemical solution containing the hydrogen peroxide.

<11>

A processing solution for a semiconductor device containing NH₃, a corrosion inhibitor, and water, in which the corrosion inhibitor is at least one selected from the group consisting of 5-methyl-1H-benzotriazole, imidazole, and 5-amino-1H-tetrazole, and a mass ratio of a content of the NH₃ to a content of the corrosion inhibitor (NH₃/corrosion inhibitor) is 5 to 60.

<12>

The processing solution for a semiconductor device according to <11>, further containing a surfactant.

<13>

The processing solution for a semiconductor device according to <11> or <12>, further containing hydrogen peroxide.

<14>

The processing solution for a semiconductor device according to any one of <11> to <13>, further containing a chelating agent.

<15>

The processing solution for a semiconductor device according to <13>, in which: the processing solution for a semiconductor device is a processing solution kit for a semiconductor device including a first chemical solution containing the NH₃, the corrosion inhibitor, and the water, and a second chemical solution containing the hydrogen peroxide; the corrosion inhibitor of the first chemical solution is at least one selected from the group consisting of 5-methyl-1H-benzotriazole, imidazole, and 5-amino-1H-tetrazole; and a mass ratio of a content of the NH₃ to a content of the corrosion inhibitor of the first chemical solution is 5 to 60.

According to the present invention, it is possible to provide a method for processing a semiconductor substrate, a method for manufacturing a semiconductor device, and a processing solution for a semiconductor device, which are excellent in the removability of a metal nitride and the anticorrosion property of a metal layer.

### BRIEF DESCRIPTION OF THE DRAWINGS

FIG. 1 is a cross-sectional view illustrating an example of a semiconductor element (semiconductor substrate) to be processed; and

FIG. 2 is a cross-sectional view illustrating another example of a semiconductor element (semiconductor substrate) to be processed.

### DETAILED DESCRIPTION

Hereinafter, an embodiment for carrying out the present invention (hereinafter simply referred to as “present embodiment”) will be described in detail. The present embodiment below is an example for describing the present invention, and it is not intended to limit the present invention to the following description. The present invention can be appropriately modified and implemented within the scope of the gist thereof.

In the drawings, the same elements are denoted by the same reference numerals, and redundant description will be omitted. Furthermore, unless otherwise specified, the positional relationship such as up, down, left, and right is based on the positional relationship illustrated in the drawings. Furthermore, the dimensional ratios in the drawings are not limited to the illustrated ratios.

### <Method for Processing Semiconductor Substrate>

A method for processing a semiconductor substrate according to the present embodiment includes a processing step of processing a semiconductor substrate including a layer containing a metal nitride with a processing solution for a semiconductor device, the processing solution for a semiconductor device containing NH₃, a corrosion inhibitor, and water, the corrosion inhibitor being at least one selected from the group consisting of 5-methyl-1H-benzotriazole, imidazole, and 5-amino-1H-tetrazole, and a mass ratio of a content of NH₃ to a content of the corrosion inhibitor (NH₃/corrosion inhibitor) is 5 to 60. According to the method for processing a semiconductor substrate according to the present embodiment, it is possible to achieve both the removability of a metal nitride such as tantalum nitride and the anticorrosion property of a metal layer containing metal atoms such as copper atoms.

The present inventor focused on the fact that the conventional processing solution has an insufficient effect of suppressing damage to a metal layer of a semiconductor substrate to be processed, and intensively studied this point. As a result, it was considered that when a metal nitride film is formed on a laminated substrate to be processed, the corrosion inhibitor is adsorbed or attached to the metal nitride film, so that the effect of adding the corrosion inhibitor is reduced.

For example, some conventional processing solutions contain an alkali component such as NH₃ or TMAH in order to clean and remove a layer containing a metal nitride. As a result of examining such problems of the conventional processing solution, the present inventors arrived at the following conclusion. Such a processing solution comes into contact with the layer containing a metal nitride, so that an alkali component in the processing solution acts to dissolve the metal nitride as a metal hydroxyl complex in the liquid. Thus, the layer containing the metal nitride can be cleaned and removed. However, the present inventors thought that there may be a problem that the metal layer containing metal atoms such as copper atoms is also dissolved in the liquid by the action, and the metal layer is also damaged.

As a result of further studies in consideration of the problems of the conventional processing solution described above, the present inventor surprisingly found that the above-described problems can be solved by using a processing solution containing NH₃, a corrosion inhibitor, and water, in which the corrosion inhibitor is at least one selected from the group consisting of 5-methyl-1H-benzotriazole, imidazole, and 5-amino-1H-tetrazole, and the mass ratio of the content of NH₃ to the content of the corrosion inhibitor (NH₃/corrosion inhibitor) is 5 to 60. The reason is not clear, but is considered as follows.

The processing solution used in the present embodiment contains NH₃ and at least one selected from the group consisting of 5-methyl-1H-benzotriazole, imidazole, and 5-amino-1H-tetrazole in a mass ratio of 5 to 60 (NH₃/corrosion inhibitor). With such a composition, NH₃ as an alkali component in the processing solution acts, and the metal nitride can be dissolved in the liquid as a metal hydroxyl complex. In addition, the above-mentioned corrosion inhibitor in the processing solution is not unintentionally adsorbed to the metal nitride, and thus does not inhibit the dissolution of the metal nitride in the liquid. From the above, it is considered that the removability of the metal nitride can be secured. On the other hand, since the corrosion inhibitor in the processing solution effectively acts as a corrosion inhibitor for the metal layer containing metal atoms such as copper atoms, the anticorrosion property of the metal layer can also be secured. From the above, according to the method for processing a semiconductor substrate according to the present embodiment, it is considered that both the removability of a metal nitride such as tantalum nitride and the anticorrosion property of a metal layer containing metal atoms such as copper atoms can be achieved (note, however, that the functions and effects of the present embodiment are not limited thereto).

The processing solution used in the present embodiment can also achieve a balance between the removability of a metal nitride and the anticorrosion property of a metal layer at a higher level by further containing an arbitrary component described later, or further satisfying conditions described later. In addition, by adopting various preferred aspects of the present embodiment, it can be expected to further impart various effects as described below in addition to the removability of a metal nitride and the anticorrosion property of a metal layer (note, however, that the functions and effects of the present embodiment are not limited thereto).

When the processing solution used in the present embodiment further contains an arbitrary component described later or satisfies an arbitrary condition described later, in a case of processing a semiconductor substrate including a carbon hard mask (CHM) layer which is an organic substance layer, it is also possible to improve the damage suppression (anticorrosion property of the CHM layer) of the CHM layer.

Furthermore, when etching is performed using a fluorine-based gas such as a fluorocarbon gas (CF gas), a fluorocarbon-based polymer (CF-based polymer) is generated as a reaction product. Even if the CF-based polymer can be once removed from the semiconductor substrate by the processing solution (or cleaning solution), the removed CF-based polymer may be reattached onto the substrate and remain as a foreign substance. Therefore, removability of the CF-based polymer is also desired. In this regard, the processing solution used in the present embodiment can also improve the removability of the CF-based polymer by further containing an arbitrary component such as a surfactant described later or further satisfying an arbitrary condition described later.

Furthermore, when the processing solution contains hydrogen peroxide, since hydrogen peroxide has a property of decomposing over time, a problem that the composition of the processing solution changes over time is likely to occur. However, even when the processing solution used in the present embodiment contains hydrogen peroxide, the temporal stability can also be improved by further containing an arbitrary component described later or further satisfying an arbitrary condition described later.

First, a semiconductor substrate to be processed will be described.

### (Semiconductor Substrate)

An object of the method for processing a semiconductor substrate according to the present embodiment is a semiconductor substrate including a layer containing a metal nitride. According to the method for processing a semiconductor substrate according to the present embodiment, at least the removability of a metal nitride and the anticorrosion property of a metal layer are excellent. Specific examples of the semiconductor substrate may include a laminated substrate including a substrate and a metal layer formed on the substrate, and a semiconductor substrate after dry etching. The semiconductor substrate (laminated substrate) to be processed may include at least a layer containing a metal nitride, but is preferably a semiconductor substrate including a first layer containing a metal nitride and a second layer containing a metal atom. As a specific example of the metal nitride, for example, at least one selected from the group consisting of tantalum nitride, titanium nitride, aluminum nitride, titanium aluminum nitride, and the like is preferable. The metal atoms of the second layer are preferably, for example, at least one selected from the group consisting of copper atoms, tungsten atoms, cobalt atoms, ruthenium atoms, and the like. A specific example of the second layer is more preferably at least one selected from the group consisting of a metal oxide, a metal nitride, a metal chloride, and a metal fluoride of metal atoms; and is further more preferably at least one selected from the group consisting of a metal oxide, a metal nitride, a metal chloride, and a metal fluoride of metal atoms, and the metal atoms are at least one selected from the group consisting of copper atoms and tantalum atoms. By providing such a layer, the advantages of the present embodiment described later can be more effectively exhibited.

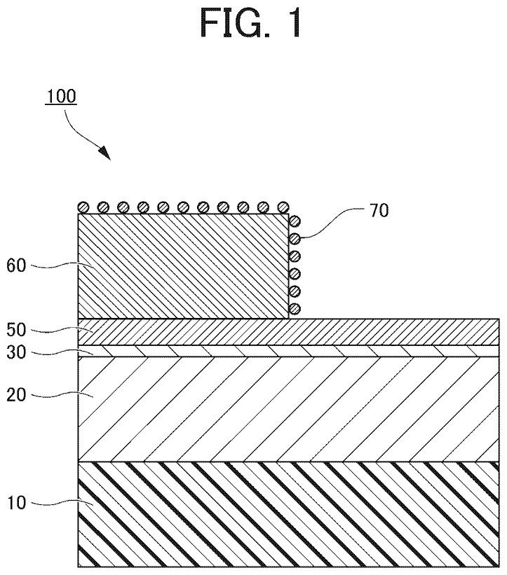

FIG. 1 is a cross-sectional view illustrating an example of a semiconductor element (semiconductor substrate) to be processed.

In a semiconductor element 100 illustrated in FIG. 1, a substrate 10, a metal wiring layer 20, an etching stop layer 30, and a tantalum nitride film (TaN film) 50 are laminated in this order, and a hard mask layer (HM layer) 60 is formed on the tantalum nitride film (TaN film) 50 (substrate 10/metal wiring layer 20/etching stop layer 30/tantalum nitride film (TaN film) 50/HM layer 60).

The semiconductor element 100 is masked by the HM layer 60 corresponding to the prototype of a wiring pattern. The semiconductor element 100 is in a state before an exposed surface of the tantalum nitride film 50 (an unmasked portion of the hard mask layer 60) is etched.

In the unmasked portion of the hard mask layer 60 having the wiring pattern shape, the tantalum nitride film 50 is exposed. In addition, a residue 70 is attached to the hard mask layer 60.

Examples of the substrate 10 may include substrate materials such as silicon, amorphous silicon, SiC, GaN, and glass.

Examples of the metal wiring layer 20 may include metal wiring layers including at least one selected from the group consisting of metals such as molybdenum (Mo), tungsten (W), ruthenium (Ru), copper (Cu), iron (Fe), gold (Au), silver (Ag), nickel (Ni), aluminum (Al), lead (Pb), zinc (Zn), tin (Sn), tantalum (Ta), magnesium (Mg), cobalt (Co), bismuth (Bi), cadmium (Cd), titanium (Ti), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), and thallium (Tl), and metal oxides, metal nitrides, metal chlorides, and metal fluorides thereof.

Note that the metal wiring layer 20 includes layers formed by using the various metals described above, and metal oxides, metal nitrides, metal chlorides, and metal fluorides thereof.

The etching stop layer 30 has a function of preventing an etching solution from entering the metal wiring layer 20. In addition, in the case of dry etching, when the ILD or the like is dry etched, the etching is stopped by the etching stop layer 30, and the lower layer is protected. Examples of the etching stop layer 30 may include a layer containing at least one selected from the group consisting of aluminum oxide, carbon-doped oxide (SiOC), silicon nitride, SiOCN, aluminum nitride, and the like.

The tantalum nitride film 50 is an example of the metal nitride film described above.

The material of the HM layer 60 may be any material as long as it functions as a protective film against etching, the material is not particularly limited, and a suitable material can be appropriately selected in consideration of manufacturing conditions and the like. The HM layer 60 is preferably, for example, a carbon hard mask (CHM) layer, a layer containing titanium and a titanium-based alloy, a layer containing Si, a layer containing tungsten carbide, or the like. For example, the CHM layer is suitably used as a mask layer in a case where deep etching is performed in a semiconductor device manufacturing process.

The residue 70 mainly includes etching residues, deposits such as CF-based polymers, CMP residues, organic residues, and the like. Examples of etching residues may include residues of various metals described above, residues of various inorganic substances described above, and the like. Since the method for processing a semiconductor substrate according to the present embodiment can also be expected to efficiently clean such residues, it can also be expected to suppress foreign matter remaining on the surface of the processed semiconductor substrate.

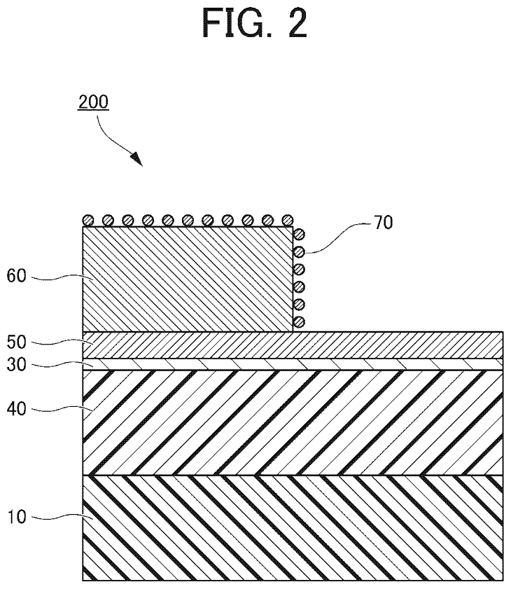

FIG. 2 is a cross-sectional view illustrating another example of the semiconductor element (semiconductor substrate) to be processed.

In a semiconductor element 200 illustrated in FIG. 2, a substrate 10, an interlayer insulating film 40, an etching stop layer 30, and a tantalum nitride film (TaN film) 50 are laminated in this order, and a hard mask layer (HM layer) 60 is formed on the tantalum nitride film (TaN film) 50 (substrate 10/interlayer insulating film 40/etching stop layer 30/tantalum nitride film (TaN film) 50/HM layer 60). The semiconductor element 200 has a configuration in which the metal wiring layer 20 of semiconductor element 100 illustrated in FIG. 1 is changed to the interlayer insulating film 40. For the substrate 10, the etching stop layer 30, the tantalum nitride film (TaN film) 50, and the hard mask layer (HM layer) 60, those described in the semiconductor element 100 can be adopted.

The material of the interlayer insulating film 40 may be any material as long as it has insulating properties, the material is not particularly limited, and a suitable material can be appropriately selected in consideration of manufacturing conditions and the like. Examples of the interlayer insulating film 40 may include layers including silicon-based materials such as SiO₂, SiN, SiOC, and SiOCN.

Next, a processing solution for a semiconductor device to be used will be described.

### (Processing Solution for Semiconductor Device)

A processing solution for a semiconductor device (hereinafter sometimes simply abbreviated as a “processing solution”) used in the method for processing a semiconductor substrate according to the present embodiment will be described. The processing solution contains NH₃, a corrosion inhibitor, and water, the corrosion inhibitor is at least one selected from the group consisting of 5-methyl-1H-benzotriazole (5MBTA), imidazole, and 5-amino-1H-tetrazole, and the mass ratio of the content of NH₃ to the content of the corrosion inhibitor (NH₃/corrosion inhibitor) is 5 to 60.

The processing solution contains NH₃. NH₃ may be added, for example, as ammonium hydroxide (NH₄OH).

The processing solution contains, as a first corrosion inhibitor, at least one selected from the group consisting of 5-methyl-1H-benzotriazole (5MBTA), imidazole, and 5-amino-1H-tetrazole. These may be used alone or in combination of two or more kinds thereof. The first corrosion inhibitor is expected to suppress damage to various metal layers, and in particular, the first corrosion inhibitor can more effectively suppress damage of a copper atom-containing component, a cobalt atom-containing component, or the like, and thus can contribute to the anticorrosion property of the metal layer.

The content of the first corrosion inhibitor in the processing solution is not particularly limited, and is preferably 0.0001 to 10% by mass. The upper limit value of the content is more preferably 6% by mass or less, even more preferably 3% by mass or less, and still more preferably 1% by mass or less. The lower limit value of the content is more preferably 0.001% by mass or more, even more preferably 0.01% by mass or more, and still more preferably 0.1% by mass or more. In a case where two or more kinds of the first corrosion inhibitor are contained, the total amount of the first corrosion inhibitor is preferably in the above range. When the content of the first corrosion inhibitor is in such a range, both the removability of a metal nitride and the anticorrosion property of a metal layer described above can be achieved at a higher level. Note that the processing solution may be stored as a concentrated solution obtained by concentrating components before being used in the processing step, and when being used in the processing step, the concentrated solution may be diluted by adding a solvent such as water and used as a diluted solution (processing solution). In that case, the content (concentration of the diluted solution) at the time of use is preferably within the above-described range.

In addition, the processing solution may further contain another corrosion inhibitor other than these as a second corrosion inhibitor. Examples of the second corrosion inhibitor may include a nitrogen-containing heterocyclic ring-containing compound, a mercapto group-containing compound, an aliphatic amine compound, and salts thereof. By containing the second corrosion inhibitor, it is possible to provide corrosion protection for metal components other than those protected by the first corrosion inhibitor.

Examples of the nitrogen-containing heterocyclic ring-containing compound may include imidazole ring-containing compounds, triazole ring-containing compounds, pyridine ring-containing compounds, pyrimidine ring-containing compounds, phenanthroline ring-containing compounds, tetrazole ring-containing compounds, pyrazole ring-containing compounds, purine ring-containing compounds, and the like.

Specific examples of the imidazole ring-containing compound may include 1-decyl-3-methylimidazolium chloride, 2-ethyl-4-methylimidazole, 2-methylimidazole, 2-ethylimidazole, 2-isopropylimidazole, 2-propylimidazole, 2-butylimidazole, 4-methylimidazole, 2,4-dimethylimidazole, 2-undecylimidazole, and 2-aminoimidazole; and 2,2′-biimidazole.

Specific examples of the triazole ring-containing compound may include 1,2,4-triazole, 1,2,3-benzotriazole, 1,2,3-triazole, 3-amino-1H-1,2,4-triazole, 1-hydroxybenzotriazole, 1-dihydroxypropylbenzotriazole, 2,3-dicarboxypropylbenzotriazole, 4-hydroxybenzotriazole, 4-carboxyl-1H-benzotriazole, 4-carboxyl-1H-benzotriazole methyl ester, 4-carboxyl-1H-benzotriazole butyl ester, 4-carboxyl-1H-benzotriazole octyl ester, 5-hexylbenzotriazole, [1,2,3-benzotriazolyl-1-methyl][1,2,4-triazolyl-1-methyl][2-ethylhexyl]amine, tolyltriazole, naphthotriazole, bis[(1-benzotriazolyl)methyl]phosphonic acid, and 3-aminotriazole.

Specific examples of the pyridine ring-containing compound may include 1H-1,2,3-triazolo[4,5-b]pyridine, 1,2,4-triazolo[4,3-a]pyridine-3(2H)-one, 3H-1,2,3-triazolo[4,5-b]pyridine-3-ol, 1-acetyl-1H-1,2,3-triazolo[4,5-b]pyridine, 3-aminopyridine, 4-aminopyridine, 3-hydroxypyridine, 4-hydroxypyridine, 2-acetamidopyridine, 4-pyrrolidinopyridine, 2-cyanopyridine, 2,2′-bipyridyl, 4,4′-dimethyl-2,2′-bipyridyl, 4,4′-di-tert-butyl-2,2′-bipyridyl, and 4,4′-dinonyl-2,2′-bipyridyl.

Specific examples of the pyrimidine ring-containing compound may include pyrimidine, 1,2,4-triazolo[1,5-a]pyrimidine, 1,3,4,6,7,8-hexahydro-2H-pyrimido[1,2-a]pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2,4,6-trimethoxypyrimidine, 2,4,6-triphenylpyrimidine, 2,4-diamino-6-hydroxylpyrimidine, 2,4-diaminopyrimidine, 2-acetamidopyrimidine, 2-aminopyrimidine, 2-methyl-5,7-diphenyl-(1,2,4)triazolo(1,5-a)pyrimidine, 2-methylsulfanyl-5,7-diphenyl-(1,2,4)triazolo(1,5-a)pyrimidine, 2-methylsulfanyl-5,7-diphenyl-4,7-dihydro-(1,2,4)triazolo(1,5-a)pyrimidine, and 4-aminopyrazolo[3,4-d]pyrimidine.

Specific examples of the phenanthroline ring-containing compound may include 1,10-phenanthroline.

Specific examples of the tetrazole ring-containing compound may include 1H-tetrazole, 5-methyl-1H-tetrazole, 5-phenyl-1H-tetrazole, and 1-(2-diaminoethyl)-5-mercaptotetrazole.

Specific examples of the pyrazole ring-containing compound may include 3,5-dimethylpyrazole, 3-amino-5-methylpyrazole, 4-methylpyrazole, and 3-amino-5-hydroxypyrazole.

Specific examples of the purine ring-containing compound may include purines.

Specific examples of the mercapto group-containing compound may include 1-thioglycerol, 3-(2-aminophenylthio)-2 hydroxypropyl mercaptan, 3-(2-hydroxyethylthio)-2 hydroxypropyl mercaptan, 2-mercaptopropionic acid, and 3-mercaptopropionic acid.

Specific examples of the aliphatic amine compound may include alkylamine, dialkylamine, and trialkylamine.

The content of the second corrosion inhibitor in the processing solution is not particularly limited, and is preferably 0.0001 to 10% by mass. The upper limit value of the content is more preferably 6% by mass or less, even more preferably 3% by mass or less, and still more preferably 1% by mass or less. The lower limit value of the content is more preferably 0.001% by mass or more, even more preferably 0.01% by mass or more, and still more preferably 0.1% by mass or more. In a case where two or more kinds of the second corrosion inhibitor are contained, the total amount of the second corrosion inhibitor is preferably in the above range. When the content of the second corrosion inhibitor is in such a range, the effect of suppressing damage to more kinds of metal layers can be exhibited, and both the removability of a metal nitride and the anticorrosion property of a metal layer described above can be achieved at a higher level. Note that the processing solution may be stored as a concentrated solution obtained by concentrating components before being used in the processing step, and when being used in the processing step, the concentrated solution may be diluted by adding a solvent such as water and used as a diluted solution (processing solution). In that case, the content (concentration of the diluted solution) at the time of use is preferably within the above-described range.

In addition, the first corrosion inhibitor and the second corrosion inhibitor may be salts of the compounds described above. Specific examples of the salt include, but are not particularly limited to, a sodium salt, a potassium salt, an ammonium salt, and an alkyl ammonium salt (e.g., tetramethylammonium salt or the like). A hydrate of the above compound may also be used. Note that in the case of a hydrate, it is preferable that the net content excluding the water of hydration contained in the hydrate is within the range described above.

The total content of the corrosion inhibitor in the processing solution (the total content of the first corrosion inhibitor and the second corrosion inhibitor) is not particularly limited, and is preferably 0.0001 to 10% by mass. The upper limit value of the content is more preferably 6% by mass or less, even more preferably 3% by mass or less, and still more preferably 1% by mass or less. The lower limit value of the content is more preferably 0.001% by mass or more, even more preferably 0.01% by mass or more, and still more preferably 0.1% by mass or more. Note that the processing solution may be stored as a concentrated solution obtained by concentrating components before being used in the processing step, and when being used in the processing step, the concentrated solution may be diluted by adding a solvent such as water and used as a diluted solution (processing solution). In that case, the content (concentration of the diluted solution) at the time of use is preferably within the above-described range.

In the processing solution, the mass ratio of the content of NH₃ to the content of the corrosion inhibitor (first corrosion inhibitor) (NH₃/first corrosion inhibitor) is 5 to 60. The upper limit value of the mass ratio is preferably 50 or less, more preferably 40 or less, even more preferably 30 or less, still more preferably 20 or less, yet still more preferably 10 or less, and yet still more preferably 9 or less. The lower limit value of the mass ratio is preferably 5.5 or more, and more preferably 6 or more. By controlling the mass ratio within such a range, at least both the removability of a metal nitride and the anticorrosion property of a metal layer can be achieved at a higher level.

The processing solution preferably further contains hydrogen peroxide. Inclusion of hydrogen peroxide is preferable because tantalum nitride and the like can be effectively etched. Some conventional processing solutions containing hydrogen peroxide may cause a problem that the efficacy of the processing solution decreases due to decomposition of hydrogen peroxide over time. However, the processing solution used in the present embodiment can effectively suppress the decomposition of hydrogen peroxide over time due to interaction with other blending components even when the processing solution contains hydrogen peroxide.

The content of hydrogen peroxide in the processing solution is not particularly limited, and is preferably 1 to 20% by mass. The upper limit value of the content is more preferably 18% by mass or less, even more preferably 16% by mass or less, and still more preferably 15% by mass or less. Moreover, the lower limit value of the content is more preferably 2% by mass or more, even more preferably 2.5% by mass or more, still more preferably 3% by mass or more, and still more preferably 4% by mass or more. When the content of hydrogen peroxide is in the above-described range, the above-described effect of adding hydrogen peroxide can be further improved. Note that the processing solution may be stored as a concentrated solution obtained by concentrating components before being used in the processing step, and when being used in the processing step, the concentrated solution may be diluted by adding a solvent such as water and used as a diluted solution (processing solution). In that case, the content (concentration of the diluted solution) at the time of use is preferably within the above-described range.

The processing solution preferably further contains a surfactant. Since the surfactant tends to have high affinity with a hydrophobic CF-based polymer, the CF-based polymer as a residue can be more effectively removed by containing the surfactant. The reason for this is presumed to be that, for example, when the CF-based polymer or the like is cleaned and removed after the etching or the like, the CF-based polymer can be removed by being adsorbed to the surfactant due to the affinity between the CF-based polymer and the surfactant (note, however, that the functions and effects of the present embodiment are not limited thereto). Note that such an action of the surfactant can be further improved by controlling the pH.

The kind of the surfactant is not particularly limited, and a surfactant having high affinity with the CF-based polymer is preferable from the viewpoint of removability of the CF-based polymer. From such a viewpoint, the surfactant is preferably a polymer-based surfactant and/or has a hydrophilic group. As a specific example of the surfactant, a nonionic surfactant is preferable, a nonionic polymeric surfactant is more preferable, and polyvinylpyrrolidone and poly (2-ethyl-2-oxazoline) are even more preferable. Such a surfactant tends to have higher affinity with a hydrophobic CF-based polymer, and thus the removability of the CF-based polymer can be further improved by using such a surfactant.

The content of the surfactant in the processing solution is not particularly limited, and is preferably 0.001 to 1% by mass. The upper limit value of the content is more preferably 0.75% by mass or less, even more preferably 0.5% by mass or less, still more preferably 0.25% by mass or less, and still more preferably 0.1% by mass or less. In addition, the lower limit value of the content is more preferably 0.005% by mass or more, even more preferably 0.007% by mass or more, and still more preferably 0.01% by mass or more. When the content of the surfactant is within the above range, the effect of adding the surfactant described above can be further improved. Note that the processing solution may be stored as a concentrated solution obtained by concentrating components before being used in the processing step, and when being used in the processing step, the concentrated solution may be diluted by adding a solvent such as water and used as a diluted solution (processing solution). In that case, the content (concentration of the diluted solution) at the time of use is preferably within the above-described range.

The processing solution preferably further contains a chelating agent. Hydrogen peroxide can be stabilized by containing a chelating agent (note, however, that the functions and effects of the present embodiment are not limited thereto).

The kind of the chelating agent is not particularly limited, and 1,2-cyclohexanediaminetetraacetic acid, ethylenediaminetetraacetic acid, etidronic acid, phenylphosphonic acid, citric acid, acetylacetone, ethylenediaminetetra (methylenephosphonic acid), 3-morpholinopropanesulfonic acid, 1,3-phenylenediacetic acid, tetraethylenepentamine, pentaethylenehexamine, and the like are preferable, and trans-1, 2-cyclohexanediaminetetraacetic acid (CyDTA) is more preferable. By using such a chelating agent, the decomposition of hydrogen peroxide over time can be more effectively suppressed.

The content of the chelating agent in the processing solution is not particularly limited, and is preferably 0.001 to 10% by mass. The upper limit value of the content is more preferably 5% by mass or less, even more preferably 3% by mass or less, still more preferably 1% by mass or less, still more preferably 0.5% by mass or less, and yet still more preferably 0.2% by mass or less. In addition, the lower limit value of the content is more preferably 0.01% by mass or more, even more preferably 0.05% by mass or more, and still more preferably 0.07% by mass or more. When the content of the chelating agent is within the above range, the effect of adding the chelating agent described above can be further improved. Note that the processing solution may be stored as a concentrated solution obtained by concentrating components before being used in the processing step, and when being used in the processing step, the concentrated solution may be diluted by adding a solvent such as water and used as a diluted solution (processing solution). In that case, the content (concentration of the diluted solution) at the time of use is preferably within the above-described range.

The processing solution may further contain components other than the above components. Examples of such components may include a pH adjusting agent and a buffer.

The processing solution preferably contains a pH adjusting agent for the purpose of adjusting the pH to a desired pH. As the pH adjusting agent, known inorganic acids, organic acids, organic basic compounds, inorganic basic compounds, and the like can be appropriately used as long as the effect of the present embodiment can be obtained.

Specific examples of the pH adjusting agent may include phosphoric acid, hydrochloric acid, sulfuric acid, methanesulfonic acid (MSA), citric acid, acetic acid, sodium dihydrogen phosphate, trisodium phosphate, sodium acetate, sodium hydroxide, sodium carbonate, sodium hydrogen carbonate, potassium hydroxide, potassium carbonate, potassium hydrogen carbonate, monoethanolamine, ammonia, ammonium carbonate, 2-amino-2-methyl-1-propanol, tripotassium citrate, and diammonium hydrogen phosphate.

The pH adjusting agent may be used alone or in combination of two or more kinds thereof. Alternatively, the processing solution used in the present embodiment does not need to contain a buffer.

The processing solution according to the present embodiment may contain a buffer. The buffer is a compound having a function of suppressing a change in pH of the processing solution. By containing the buffer, it is possible to efficiently control the pH of the processing solution to a predetermined value. The buffer is not particularly limited as long as it is a compound having pH buffering ability. Examples of the buffer may include Good's buffering agent.

The buffer may be used alone or in combination of two or more kinds thereof. Alternatively, the processing solution used in the present embodiment does not need to contain a buffer.

The processing solution used in the present embodiment may contain a solvent. The solvent preferably contains water. The processing solution in this case can be suitably used as an aqueous processing solution. An example of the aqueous processing solution may include an aqueous processing solution containing water as the remainder excluding the active ingredient.

The content of water in the processing solution is not particularly limited, and is preferably 1 to 99.99% by mass. The lower limit value of the content is more preferably 50% by mass or more, even more preferably 60% by mass or more, still more preferably 70% by mass or more, and yet still more preferably 80% by mass or more from the viewpoint of being able to maintain the residue removing property and the anticorrosion property at a high level while imparting water solubility as the aqueous processing solution. In addition, the upper limit value of the content is more preferably 99.9% by mass or less, even more preferably 99% by mass or less, still more preferably 98% by mass or less, and yet still more preferably 95% by mass or less from the viewpoint of being able to maintain the residue removing property and the anticorrosion property at a high level while imparting water solubility as the aqueous processing solution. When the content of water is within the above range, other components can be uniformly and stably dissolved.

Note that in the method for processing a semiconductor substrate according to the present embodiment, it is preferable that the content of water in the processing solution when the semiconductor substrate is processed with the processing solution for a semiconductor device is within the above-described range; however, a step of concentrating the processing solution before use in the processing step so as to reduce the content of water and adding water when use in the processing step so as to make the content within the above-described range may be performed.

The processing solution according to the present embodiment may contain an organic solvent. Specific examples of the organic solvent are not particularly limited, and at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent is preferable. Furthermore, it is more preferable that the processing solution contains, as an organic solvent, only at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent, and does not contain any other solvent. When the processing solution contains an organic solvent, it is preferable to use a water-soluble organic solvent from the viewpoint of the water solubility of the processing solution.

The organic solvent may be used alone or in combination of two or more kinds thereof.

The processing solution used in the present embodiment can achieve a sufficient effect without containing an organic solvent, but can also achieve a sufficient effect even when containing an organic solvent. That is, the processing solution according to the present embodiment may contain an organic solvent. From such a viewpoint, the content of the organic solvent in the present embodiment can be 0 to 95% by mass. The lower limit value of the content of the organic solvent may be 0% by mass, or may be, for example, 5% by mass or more, 10% by mass or more, 20% by mass or more, 30% by mass or more, 40% by mass or more, 50% by mass or more, or 60% by mass or more, depending on the component of the processing solution or the like. In addition, the upper limit value of the content of the organic solvent may be 90% by mass or less, may be 80% by mass or less, and may be 70% by mass or less. Note that the processing solution may be stored as a concentrated solution obtained by concentrating components before being used in the processing step, and when being used in the processing step, the concentrated solution may be diluted by adding a solvent such as water and used as a diluted solution (processing solution).

(pH)

The pH of the processing solution is not particularly limited, and is preferably 7.0 to 14.0. This upper limit value is more preferably 13.0 or less, even more preferably 12.0 or less, and still more preferably 11 or less. In addition, the lower limit value is more preferably 8.0 or more, even more preferably 9.0 or more, and still more preferably 10.0 or more. When the pH of the processing solution is in such a range, both the removability of a metal nitride and the anticorrosion property of a metal layer can be achieved at a higher level. Furthermore, the removability of the CF-based polymer can be further improved. Note that the processing solution may be stored as a concentrated solution obtained by concentrating components before being used in the processing step, and when being used in the processing step, the concentrated solution may be diluted by adding a solvent such as water and used as a diluted solution (processing solution). In that case, the content (concentration of the diluted solution) at the time of use is preferably within the above-described range.

### (Impurities and the Like of Processing Solution)

The processing solution used in the present embodiment may contain, for example, a metal impurity containing at least one selected from the group consisting of Fe atoms, Cr atoms, Ni atoms, Zn atoms, Ca atoms, and Pb atoms.

The total content of metal atoms in the processing solution used in the present embodiment is preferably 100 ppt by mass or less with respect to the total mass of the processing solution. The lower limit value of the total content of the metal atoms is preferably as low as possible, and is, for example, 0.001 ppt by mass or more. The total content of the metal atoms is, for example, 0.001 to 100 ppt by mass. By setting the total content of the metal atoms to be equal to or less than the above-described preferred upper limit value, it is considered that the defect suppressing property and the residue suppressing property of the processing solution are improved. It is considered that when the total content of the metal atoms is set to be equal to or more than the above-described preferred lower limit value, the metal atoms hardly exist in the system separately, and the manufacturing yield of the entire target to be processed is hardly adversely affected.

The content of the metal impurities can be adjusted, for example, by a purification process such as filtering. The purification process such as filtering may be performed on a part or all of the raw materials before preparing the processing solution or may be performed after the processing solution is prepared.

The processing solution used in the present embodiment may contain, for example, impurities derived from organic substances (organic impurities). The total content of the organic impurities in the processing solution used in the present embodiment is preferably 5,000 ppm by mass or less. The lower limit value of the content of the organic impurities is preferably as low as possible, and is, for example, 0.1 ppm by mass or more. The total content of the organic impurities is, for example, 0.1 to 5000 ppm by mass.

The processing solution used in the present embodiment may contain, for example, targets to be counted having a size countable by a light scattering type in-liquid particle counter. The size of the target to be counted is, for example, 0.04 m or more. The number of the targets to be counted in the processing solution used in the present embodiment per 1 mL of the processing solution is, for example, 1,000 or less, and the lower limit value is, for example, 0.1 or more. It is considered that, when the number of targets to be counted in the processing solution is within the range described above, the effect of preventing metal corrosion, the effect of reducing defects, and the like by the processing solution are improved (note, however, that the functions and effects of the present embodiment are not limited thereto).

The organic impurities and/or the targets to be counted described above may be added to the processing solution or may be inevitably mixed into the processing solution in a manufacturing process of the processing solution. Examples of cases where the organic impurities are inevitably mixed in the manufacturing process of the processing solution may include a case where the organic impurities are included in a raw material (e.g., an organic solvent) used for manufacturing the processing solution, and a case where the organic impurities are mixed from an external environment in the manufacturing process of the processing solution (e.g., contamination), and the embodiment is not limited thereto.

When the targets to be counted are added to the processing solution, an abundance ratio may be adjusted for each specific size considering surface roughness and the like of the object to be processed.

Subsequently, steps of the method for processing a semiconductor substrate according to the present embodiment will be described.

### (Each Step)

The method for processing a semiconductor substrate according to the present embodiment includes a processing step of processing a semiconductor substrate with a processing solution for a semiconductor device. As the processing step, for example, by bringing a processing solution into contact with a semiconductor substrate (as an example, semiconductor element 100 and the like illustrated in FIG. 1) to be processed, a predetermined film (a layer containing a metal nitride or the like) to be removed is removed, and a residue is removed without damaging a metal layer to be protected. Hereinafter, a case where the semiconductor element 100 illustrated in FIG. 1 is cleaned will be described as an example.

The processing method according to the present embodiment is a step of processing the semiconductor element 100 after dry etching is performed by a wiring process using the above-described processing solution. The processing method is not particularly limited, and a known method can be used.

Before the processing, the processing solution may be stored as a concentrated solution concentrated to a high concentration, and immediately before the processing, a solvent may be added to dilute the processing solution to a desired concentration to prepare the processing solution. For example, an operation may be performed in which the processing solution is concentrated to 2 to 2000 times the desired concentration during use, then the concentrated solution is diluted to a desired concentration at the time of processing (at the time of use) to create a diluted solution (processing solution), and the diluted solution is used for processing.

Examples of the processing operation may include a method of continuously applying the processing solution on the semiconductor element 100 rotating at a constant speed (rotational application method), a method of immersing the semiconductor element 100 in the processing solution for a certain period of time (dipping method), and a method of spraying the processing solution on a surface of the semiconductor element 100 (spraying method).

The processing temperature (temperature of the processing solution) is not particularly limited, and is preferably 10 to 80° C. The lower limit value is more preferably 20° C. or higher and even more preferably 40° C. or higher. In addition, the upper limit value is more preferably 75° C. or lower and even more preferably 70° C. or lower. By setting the lower limit value of the processing temperature within the range described above, it is possible to further improve the removability of etching residues. In addition, by setting the upper limit value of the processing temperature within the range described above, it is possible to more effectively suppress an unintended composition change of the processing solution, and it is possible to more efficiently perform cleaning from the viewpoint of workability, safety, cost, and the like.

As the processing time, a sufficient time for removing the tantalum nitride film 50 can be appropriately selected. The processing time is preferably 10 seconds to 30 minutes, for example. The lower limit value is more preferably 20 seconds or longer and even more preferably 30 seconds or longer. Moreover, the upper limit value is more preferably 15 minutes or less, and even more preferably 10 minutes or less.

Since the processing is performed using the processing solution, in the semiconductor element 100 with the residue 70, the tantalum nitride film 50 can be removed while suppressing damage to the metal wiring layer 20. In addition, it can also be expected that a dry etching residue or the like derived from the HM layer 60, which is a protective film, is also cleaned and removed.

Furthermore, the processing solution used in the present embodiment can obtain a practically usable cleaning effect without using conventional general-purpose hydroxylamine or the like, and thus has an advantage that the semiconductor element or the like can be more safely manufactured.

When the processing solution to be used contains hydrogen peroxide, it is preferable to further include a preparation step of preparing the processing solution by mixing a first chemical solution containing NH₃, a corrosion inhibitor, and water with a second chemical solution containing hydrogen peroxide before the processing step described above. By preparing the first chemical solution and the second chemical solution in advance, mixing them before (preferably immediately before) the processing step to prepare a processing solution, and then using the processing solution, the decomposition of hydrogen peroxide over time can be effectively suppressed, and thus a desired processing effect can be further improved.

The first chemical solution may contain components other than NH₃, a corrosion inhibitor, and water. For example, other components such as the above-described pH adjusting agent and buffer may be further contained. The first chemical solution may further contain the organic solvent described above as a solvent.

The second chemical solution may contain components other than hydrogen peroxide and water. For example, other components such as the above-described pH adjusting agent and buffer may be further contained. The second chemical solution may further contain the organic solvent described above as a solvent. However, from the viewpoint of suppressing the temporal decomposition of hydrogen peroxide, it is preferable to contain only hydrogen peroxide and water. For example, hydrogen peroxide water or the like is preferably used as the second chemical solution.

Furthermore, another chemical solution (e.g., a third chemical solution, a fourth chemical solution, or the like) other than the first chemical solution and the second chemical solution may also be prepared, and the first chemical solution, the second chemical solution, and the other chemical solution may be mixed before the processing step to prepare the processing solution. Examples of the other chemical solution may include a chemical solution containing water and other components such as the above-described pH adjusting agent and buffer. The other chemical solution may further contain the organic solvent described above as a solvent.

When the first chemical solution and the second chemical solution are separately prepared as described above, the first chemical solution and the second chemical solution can be used as a processing solution kit for a semiconductor device (hereinafter sometimes simply abbreviated as a “processing solution kit”). That is, the method for processing a semiconductor substrate can further include, before the above-described processing step, a step of preparing a processing solution kit containing a first chemical solution and a second chemical solution, and a step of mixing the first chemical solution and the second chemical solution to prepare a processing solution.

### <Method for Manufacturing Semiconductor Device>

The method for processing a semiconductor substrate according to the present embodiment described above can be suitably used as one step of the method for manufacturing a semiconductor device. That is, an example of the method for manufacturing a semiconductor device according to the present embodiment may include a step of preparing a semiconductor substrate including a layer containing a metal nitride subjected to etching, and a processing step of processing the semiconductor substrate subjected to etching with a processing solution for a semiconductor device. The processing solution for a semiconductor device contains NH₃, a corrosion inhibitor, and water, the corrosion inhibitor is at least one selected from the group consisting of 5-methyl-1H-benzotriazole, imidazole, and 5-amino-1H-tetrazole, and the mass ratio of the content of NH₃ to the content of the corrosion inhibitor (NH₃/corrosion inhibitor) is 5 to 60.

### (1) Step of Preparing Semiconductor Substrate Subjected to Etching

A semiconductor substrate subjected to etching can be prepared by etching a substrate (substrate before etching) including a layer containing a metal nitride. For example, in the case of FIG. 1, although not illustrated, a laminate (substrate 10/metal wiring layer 20/etching stop layer 30/tantalum nitride film (TaN film) 50/HM layer 60) including the substrate 10, the metal wiring layer 20, the etching stop layer 30, the tantalum nitride film (TaN film) 50, and the hard mask layer (HM layer) 60 corresponding to a protective film in this order before etching is prepared, and a step of etching the laminate is performed, so that a semiconductor substrate subjected to etching can be prepared. Note that a method of sequentially laminating the substrate 10, the metal wiring layer 20, the etching stop layer 30, the tantalum nitride film (TaN film) 50, and the hard mask layer (HM layer) 60 corresponding to the protective film on the substrate 10 is not particularly limited, and a known method can be adopted.

The etching method is not particularly limited, and may be wet etching or dry etching, but is preferably dry etching. In the case of dry etching, it is advantageous from the viewpoint that metal wiring at a nano level by anisotropic etching is possible and gas to be used can be controlled. In addition, in the case of dry etching, there is a concern that damage to the substrate and the like is relatively large, but it is also desirable that the advantages of the present embodiment can be more effectively reflected from the viewpoint that such damage can be effectively suppressed by using the processing solution used in the present embodiment.

In the case of dry etching, plasma can be used. Usually, when plasma etching is performed, there is a problem that the substrate is easily damaged, or a problem that plasma etching residues are generated and it is necessary to clean the plasma etching residues with a processing solution. According to the present embodiment, it is also desirable that such problems can be effectively suppressed.

(2) Processing Step of Processing Semiconductor Substrate Subjected to Etching with the Above-Mentioned Processing Solution.

As step (2), the above-described method for processing a semiconductor substrate can be used. Thus, the semiconductor element 100 can be obtained. As the processing conditions, the conditions described in the method for processing a semiconductor substrate can be appropriately adopted. As for the composition and characteristics of the processing solution to be used, the contents described in the method for processing a semiconductor substrate can be appropriately adopted.

When the processing solution contains hydrogen peroxide, it is preferable to further include a preparation step of preparing the processing solution by mixing a first chemical solution containing NH₃, a corrosion inhibitor, and water with a second chemical solution containing hydrogen peroxide before the processing step. By preparing the first chemical solution and the second chemical solution in advance, mixing them before (preferably immediately before) the processing step to prepare a processing solution, and then using the processing solution, the decomposition of hydrogen peroxide over time can be effectively suppressed, and thus a desired processing effect can be further improved.

For the first chemical solution and the second chemical solution, the contents described as the method for processing a semiconductor substrate can be adopted. When the first chemical solution and the second chemical solution are separately prepared as described above, the first chemical solution and the second chemical solution can be used as a processing solution kit for a semiconductor device (hereinafter sometimes simply abbreviated as a “processing solution kit”). That is, the method for processing a semiconductor substrate can further include, before the above-described processing step, a step of preparing a processing solution kit containing a first chemical solution and a second chemical solution, and a step of mixing the first chemical solution and the second chemical solution to prepare a processing solution.

Then, when a chemical solution (e.g., a third chemical solution, a fourth chemical solution, or the like) other than the first chemical solution and the second chemical solution is also used in combination, the contents described as the method for processing a semiconductor substrate can also be adopted for this.

Further, if necessary, post-processing such as a rinsing step can be performed after the processing step. The rinsing step can be performed, for example, under cleaning conditions such as room temperature for 30 seconds using ultrapure water, isopropyl alcohol, ammonia water, or a mixed solution thereof, or a composition containing various additives.

### <Processing Solution for Semiconductor Device and Processing Solution Kit for Semiconductor Device>

Examples of the processing solution for a semiconductor device (processing solution) according to the present embodiment may include a processing solution for a semiconductor device containing NH₃, a corrosion inhibitor, and water, in which the corrosion inhibitor is at least one selected from the group consisting of 5-methyl-1-H-benzotriazole, imidazole, and 5-amino-1H-tetrazole, and the mass ratio of the content of NH₃ to the content of the corrosion inhibitor (NH₃/corrosion inhibitor) is 5 to 60. Such a processing solution is suitably used in the above-described method for processing a semiconductor substrate and method for manufacturing a semiconductor device. For the composition and characteristics of the processing solution, the contents described in the above-described method for processing a semiconductor substrate and method for manufacturing a semiconductor device can be appropriately adopted.

The processing solution according to the present embodiment can also be a processing solution kit for a semiconductor device (processing solution kit) including a plurality of chemical solutions depending on the use mode thereof. For example, when the processing solution contains hydrogen peroxide, a processing solution kit is preferably used from the viewpoint of securing temporal stability of hydrogen peroxide. Examples of the processing solution kit may include a processing solution kit for a semiconductor device including a first chemical solution containing NH₃, a corrosion inhibitor, and water, and a second chemical solution containing hydrogen peroxide, in which the corrosion inhibitor of the first chemical solution is at least one selected from the group consisting of 5-methyl-1H-benzotriazole, imidazole, and 5-amino-1H-tetrazole, and the mass ratio of the content of NH₃ to the content of the corrosion inhibitor of the first chemical solution is 5 to 60.

For the configuration of the processing solution kit (first chemical solution, second chemical solution, other chemical solution usable as necessary, and the like), the contents described in the above-described method for processing a semiconductor substrate and method for manufacturing a semiconductor device can be appropriately adopted.

The processing solution according to the present embodiment is suitable for removing etching residues, and is particularly suitable for removing dry etching residues. Normally, dry etching residues are removed before the next step from the viewpoint of improving the yield of the semiconductor and preventing deterioration of electrical characteristics. For example, the processing solution according to the present embodiment is suitable for cleaning a semiconductor substrate after dry etching is performed by a wiring process.

### Examples

The present invention is described in more detail with reference to the following examples and comparative examples, but the present invention is not limited to the following examples at all.

Note that the abbreviations and the English notation of the components and the like are as follows.
5MBTA: 5-methyl-1H-benzotriazole
P2E2O: poly (2-ethyl-2-oxazoline)
CyDTA: monohydrate of trans-1,2-cyclohexanediaminetetraacetic acid
Imidazole: imidazole
1,2,4-Triazole: 1,2,4-triazole
1,2,3-Benzotriazole: 1,2,3-benzotriazole
5-Amino tetrazole: 5-amino-1H-tetrazole
DBS: dodecylbenzenesulfonic acid
POEA GE: polyoxyethylene acetylene glycol ether
PVP: polyvinylpyrrolidone
DIW: deionized water

### 1. Preparation of Processing Solution (Examples 1 to 13, Comparative Examples 1 to 7)

A processing solution for a semiconductor device of each of examples and comparative examples was prepared by blending each component and water as the balance in the proportions shown in Tables 1 to 3. Specifically, an aqueous solution of a component other than hydrogen peroxide and hydrogen peroxide water were prepared, mixed, to prepare a processing solution for a semiconductor device, and then immediately subjected to each evaluation. For example, Example 1 is an aqueous processing solution containing 4.1% by mass of NH₃, 12% by mass of hydrogen peroxide (H₂O₂), 0.5% by mass of 5MBTA, and 83.4% by mass of water as the balance (see Table 1). The mass ratio of NH₃ to the corrosion inhibitor (5MBTA) is 8.2, and the pH of the aqueous processing solution is 10.2. Incidentally, as for the content (% by mass) of the hydrate, the content excluding the hydrated water contained in the hydrate is described in each table unless otherwise specified.

### (Method for Measuring pH)

The pH of the processing solution was measured using a pH/ORP meter (portable pH meter “ORION STAR A324”, manufactured by Thermo Scientific) under a temperature condition of 22° C.

### 2. Evaluation of Removability of Tantalum Nitride Film

The removability of a tantalum nitride film of each example and each comparative example was evaluated (“TaN removability” in Tables 1 to 3) by the following method (evaluation based on removal time).

First, a laminate (substrate including Cu layer, SiOC layer, TaN layer, and CHM layer) including a Cu layer (film thickness: 65 nm), a SiOC layer (film thickness: 2 nm), a TaN layer (film thickness: 9 nm), and a CHM layer (film thickness: 70 nm) on a substrate (12 inch silicon substrate) was prepared by a CVD method and dry etching. The laminate was cut into a size of 2 cm×2 cm in top view to prepare a test sample (laminate).

Subsequently, the obtained sample (laminate) was cleaned. Cleaning was performed by the following method. First, the processing solution of each example and each comparative example was heated to 58° C. Subsequently, an etched sample was immersed in the processing solution of each example and comparative example at 58° C. Thereafter, the sample was pulled up from the processing solution, cleaned with isopropyl alcohol, and then dried by blowing nitrogen. Note that in Examples 6 to 13 and Comparative Examples 5 to 7 (see Tables 2 and 3), the processed sample was rinsed with water (DIW). Then, the remaining state of the TaN film of this sample was confirmed by TEM (imaging magnification: 330k times). Specifically, the TaN removability was evaluated by measuring the time required until the TaN film was not confirmed on the exposed surface. The shorter the removal time, the better the removability.

### 3. Evaluation of Anticorrosion Property of Cu Layer

The evaluation of the anticorrosion property of the Cu layer of each example and each comparative example (“Cu corrosion@10 min” in Tables 1 to 3) was performed by the following method.

First, a laminate (substrate having a Cu metal layer) in which a metal layer of Cu (film thickness: 65 nm) was formed on a substrate (12 inch silicon substrate) by a CVD method and dry etching was prepared. The laminate was cut into a size of 2 cm×2 cm in top view to obtain a test sample (wafer coupon). Then, 80 mL of the processing solution of each example and each comparative example was placed in a 100 mL cup. A sample was put into the processing solution, and the sample was immersed in the processing solution under processing conditions of a temperature described in the table for 10 minutes. Note that during the immersion, the processing solution was stirred at 300 rpm. After the immersion, the sample was removed from the processing solution, cleaned with water at room temperature for 30 seconds, and dried by nitrogen blow. Note that in Examples 6 to 13 and Comparative Examples 5 to 7 (see Tables 2 and 3), the processed sample was rinsed with water (DIW). Then, the surface of the processed sample was observed under an imaging condition of 10k times using a scanning electron microscope (SEM), and the anticorrosion property of the Cu layer was evaluated on the basis of the degree of the residual Cu layer.

Then, the Cu layer was evaluated in terms of the anticorrosion property (“Cu corrosion@10 min”) on the basis of the following criteria.

A: There was no surface abnormality, and corrosion of the Cu wiring was not confirmed.

B: Some Cu wiring was corroded.

C: A large part of the Cu wiring was corroded.

D: Most of the Cu wiring was corroded.

As shown in Tables 1 to 3 described later, in Comparative Examples 1 to 7, at least one of the removability of the tantalum nitride film (“TaN removability”) and the anticorrosion property of the Cu layer (“Cu corrosion@10 min”) was insufficient. On the other hand, in Examples 1 to 13, it was confirmed that both the removability of the tantalum nitride film and the anticorrosion property of the Cu layer were good results. Therefore, in Examples 1 to 13, the anticorrosion property of the CHM layer, the cleanability of the CF-based polymer, and the degradability were also evaluated as additional evaluations. Hereinafter, each evaluation will be described.

### 4. Evaluation of Anticorrosion Property of CHM Layer

The evaluation of the anticorrosion property of the carbon hard mask (CHM) layer of each example (“CHM@Clean time” in Tables 1 to 3) was performed by the following method.

First, a laminate (substrate having a CHM layer) having a CHM layer (film thickness: 70 nm) was prepared on a substrate (12 inch silicon substrate) by a CVD method and etching. The laminate was cut into a size of 2 cm×2 cm in top view to obtain a test sample (laminate). Then, 80 mL of the processing solution of each example was placed in a 100 mL cup. A sample was put into the processing solution, and the sample was immersed in the processing solution under processing conditions of a temperature described in the table for 10 minutes. Note that during the immersion, the processing solution was stirred at 300 rpm. After the immersion, the sample was removed from the processing solution, cleaned with water at room temperature for 30 seconds, and dried by nitrogen blow. Note that in Examples 6 to 13 (see Tables 2 and 3), the processed sample was rinsed with water (DIW). Then, the surface of the processed sample was observed under an imaging condition of 10k times using a scanning electron microscope (SEM), and the anticorrosion property of the CHM layer was evaluated on the basis of the degree of the residual CHM layer.

The anticorrosion property of the CHM layer (“CHM@Clean time”) was evaluated on the basis of the following criteria.

A: The CHM layer remained.

B: A part of the CHM layer was removed.

C: All of the CHM layer was removed.

### 5. Evaluation of Cleanability of CF-Based Polymer

The evaluation of the cleanability of the CF-based polymer of each example (“CF polymer@Clean time” in Tables 1 to 3) was performed by the following method.

The test sample prepared in “2. Evaluation of removability of tantalum nitride film” was used as a sample for this evaluation. Then, 80 mL of the processing solution of each example was placed in a 100 mL cup. A sample was put into the processing solution, and the sample was immersed in the processing solution under processing conditions of a temperature described in the table for 10 minutes. Note that during the immersion, the processing solution was stirred at 300 rpm. After the immersion, the sample was removed from the processing solution, cleaned with water at room temperature for 30 seconds, and dried by nitrogen blow. Note that in Examples 6 to 13 (see Tables 2 and 3), the processed sample was rinsed with water (DIW). Then, the surface of the processed sample was observed under an imaging condition of 10k times using a scanning electron microscope (SEM). Then, the cleanability of the CF-based polymer was evaluated on the basis of the degree of cleaning of the CF-based polymer.

The cleanability (“CF polymer@Clean time”) of the CF-based polymer was evaluated on the basis of the following criteria.

A: No CF-based polymer was confirmed on the surface of the sample.

B: It was confirmed that the CF-based polymer remained on the surface of the sample.

### 6. Evaluation of Degradability (Temporal Stability)

The evaluation of the degradability (temporal stability) of the processing solution of each example (“Decomposition” in Tables 1 to 3) was performed by the following method.

In a transparent container made of perfluoroalkoxy alkane (PFA), 100 mL of the processing solution of each example was placed, heated to 58° C., and four small pieces (2 cm×5 cm) of a TaN substrate (film thickness: 20 nm) were immersed for 30 minutes. Thereafter, the frequency of large bubbles having a diameter of about 0.5 cm floating up to the surface of the chemical solution from the chemical solution was observed from a side surface of the container to evaluate the degree of degradability of the processing solution.

The degradability (temporal stability, “Decomposition”) of the processing solution was evaluated on the basis of the following criteria.

A: The frequency of bubbles was low (nine or less in one minute).

B: The frequency of bubbles was high (10 or more bubbles in one minute).

Tables 1 to 3 show compositions, characteristics, processing conditions, and evaluation results of the processing solutions of the examples and comparative examples.

TABLE 1

| | | Example | Example | Example | Example | Example | Comparative | Comparative | Comparative | Comparative |
|---|---|---|---|---|---|---|---|---|---|---|
| | | 1 | 2 | 3 | 4 | 5 | Example 1 | Example 2 | Example 3 | Example 4 |
| Composition | NH₃ | 4.1 | 3 | 3 | 3 | 3 | 4.1 | 4.1 | 4.1 | 3 |
| [wt %] | H₂O₂ | 12 | 12 | 12 | 12 | 12 | 4.3 | 8 | 12 | 12 |
| | 5MBTA | 0.5 | 0.5 | 0.5 | 0.5 | 0.5 | 0 | 0 | 0 | 0 |
| | (Corrosion | | | | | | | | | |
| | inhibitor) | | | | | | | | | |
| | P2E2O | 0 | 0 | 0 | 0.1 | 0.1 | 0 | 0 | 0 | 0 |
| | CyDTA | 0 | 0 | 0.1 | 0 | 0.1 | 0 | 0 | 0 | 0 |
| | DIW | 83.4 | 84.5 | 84.4 | 84.4 | 84.3 | 91.6 | 87.9 | 83.9 | 85 |

| NH₃/Corrosion | 8.2 | 6 | 6 | 6 | 6 | — | — | — | — |
|---|---|---|---|---|---|---|---|---|---|
| inhibitor | | | | | | | | | |
| pH | 10.2 | 10.1 | 10.1 | 10.1 | 10.1 | 10.7 | 10.5 | 10.2 | 10.1 |
| Temperature | 58 deg. | 58 deg. | 58 deg. | 58 deg. | 58 deg. | 58 deg. | 58 deg. | 58 deg. | 58 deg. |
| | C. | C. | C. | C. | C. | C. | C. | C. | C. |
| TaN removability | <3 min | 2-3 min | 1.5-2 min | 2-3 min | 1.5-2 min | 5-10 min | 3-5 min | <3 min | <3 min |
| Cu corrosion | B | A | A | A | A | D | D | D | C |
| @10 min | | | | | | | | | |
| CHM @Clean time | A | A | A | A | A | | | | |
| CF polymer | B | B | A | A | A | | | | |
| @Clean time | | | | | | | | | |
| Decomposition | B | B | A | B | A | | | | |

TABLE 2

| | | Example | Example | Example | Comparative | Comparative | Comparative |
|---|---|---|---|---|---|---|---|
| | | 6 | 7 | 8 | Example 5 | Example 6 | Example 7 |
| Composition | NH₃ | 4.1 | 4.1 | 4.1 | 4.1 | 4.1 | 4.1 |
| [wt %] | H₂O₂ | 12 | 12 | 12 | 12 | 12 | 12 |
| | Corrosion | Imidazole | 5MBTA | 5-Amino | no | 1,2,4 | 1,2,3- |
| | inhibitor | 0.5 | 0.5 | tetrazole | 0 | Triazole | Benzotriazol |
| | | | | 0.5 | | 0.5 | 0.5 |
| | P2E2O | 0 | 0 | 0 | 0 | 0 | 0 |
| | CyDTA | 0 | 0 | 0 | 0 | 0 | 0 |
| | DIW | 83.4 | 83.4 | 83.4 | 83.9 | 83.4 | 83.4 |

| | | | | | | |
|---|---|---|---|---|---|---|
| NH₃/Corrosion | 8.2 | 8.2 | 8.2 | — | 8.2 | 8.2 |
| inhibitor | | | | | | |
| pH | 10.2 | 10.2 | 10.2 | 10.2 | 10.2 | 10.2 |
| Temperature | 58 deg. C. | 58 deg. C. | 58 deg. C. | 58 deg. C. | 58 deg. C. | 58 deg. C. |
| Rinse | DIW | DIW | DIW | DIW | DIW | DIW |
| TaN removability | <3 min | <3 min | <3 min | <3 min | <3 min | <3 min |
| Cu corrosion | B | B | B | D | D | D |
| @10 min | | | | | | |
| CHM @Clean time | A | A | A | | | |
| CF polymer | B | B | B | | | |
| @Clean time | | | | | | |
| Decomposition | B | B | B | | | |

TABLE 3

| | | Example | Example | Example | Example | Example |
|---|---|---|---|---|---|---|
| | | 9 | 10 | 11 | 12 | 13 |
| Composition | NH₃ | 3 | 3 | 3 | 3 | 3 |
| [wt %] | H₂O₂ | 12 | 12 | 12 | 12 | 12 |
| | 5MBTA | 0.5 | 0.5 | 0.5 | 0.5 | 0.5 |
| | (Corrosion | | | | | |
| | inhibitor) | | | | | |
| | Surfactant | DBS | POEA · GE | PVP | P2E2O | no |
| | | 0.1 | 0.1 | 0.1 | 0.1 | 0 |
| | CyDTA | 0 | 0 | 0 | 0 | 0 |
| | DIW | 84.4 | 84.4 | 84.4 | 84.4 | 84.5 |

| | | | | | |
|---|---|---|---|---|---|
| NH₃/Corrosion | 6 | 6 | 6 | 6 | 6 |
| inhibitor | | | | | |
| pH | 10.1 | 10.1 | 10.1 | 10.1 | 10.7 |
| Temperature | 58 deg. C. | 58 deg. C. | 58 deg. C. | 58 deg. C. | 58 deg. C. |
| Rinse | DIW | DIW | DIW | DIW | DIW |
| TaN removability | <3 min | <3 min | <3 min | <3 min | <3 min |
| Cu corrosion | A | A | A | A | A |
| @10 min | | | | | |
| CHM @Clean time | A | A | A | A | A |
| CF polymer | B | B | A | A | B |
| @Clean time | | | | | |
| Decomposition | B | B | B | B | B |

From the above, according to the present example, it was at least confirmed that the removability of a metal nitride and the anticorrosion property of a metal layer are excellent. Furthermore, in the case of a more preferred aspect in the present example, it was at least confirmed that any one or more of the anticorrosion property of the CHM layer, the cleanability of the CF-based polymer, and the degradability can be made excellent in addition to the removability of a metal nitride and the anticorrosion property of a metal layer.

### REFERENCE SIGNS LIST

10: substrate
20: metal wiring layer
30: etching stop layer
40: interlayer insulating film
50: tantalum nitride film (TaN film)
60: hard mask layer (HM layer)
70: residue
100, 200: semiconductor element

What is claimed is:

1. A method for processing a semiconductor substrate comprising
a processing step of processing a semiconductor substrate including a layer containing a metal nitride with a processing solution for a semiconductor device, wherein:
the processing solution for a semiconductor device contains NH₃, a corrosion inhibitor, and water;
the corrosion inhibitor is at least one selected from the group consisting of 5-methyl-1H-benzotriazole, imidazole, and 5-amino-1H-tetrazole; and
a mass ratio of a content of the NH₃ to a content of the corrosion inhibitor (NH₃/corrosion inhibitor) is 5 to 60.

2. The method for processing a semiconductor substrate according to claim 1, wherein
the processing solution for a semiconductor device further contains hydrogen peroxide.

3. The method for processing a semiconductor substrate according to claim 1, wherein
the processing solution for a semiconductor device further contains a surfactant.

4. The method for processing a semiconductor substrate according to claim 1, wherein
the processing solution for a semiconductor device further contains a chelating agent.

5. The method for processing a semiconductor substrate according to claim 2, further comprising,
before the processing step,
a preparation step of preparing the processing solution for a semiconductor device by mixing a first chemical solution containing the NH₃, the corrosion inhibitor, and the water with a second chemical solution containing the hydrogen peroxide.

6. A method for manufacturing a semiconductor device comprising:
a step of preparing a semiconductor substrate including a layer containing a metal nitride subjected to etching; and
a processing step of processing the semiconductor substrate subjected to the etching with a processing solution for a semiconductor device, wherein:
the processing solution for a semiconductor device contains NH₃, a corrosion inhibitor, and water;
the corrosion inhibitor is at least one selected from the group consisting of 5-methyl-1H-benzotriazole, imidazole, and 5-amino-1H-tetrazole; and
a mass ratio of a content of the NH₃ to a content of the corrosion inhibitor (NH₃/corrosion inhibitor) is 5 to 60.

7. The method for manufacturing a semiconductor device according to claim 6, wherein
the processing solution for a semiconductor device further contains hydrogen peroxide.

8. The method for manufacturing a semiconductor device according to claim 6, wherein
the processing solution for a semiconductor device further contains a surfactant.

9. The method for manufacturing a semiconductor device according to claim 6, wherein
the processing solution for a semiconductor device further contains a chelating agent.

10. The method for manufacturing a semiconductor device according to claim 7, further comprising,
before the processing step,
a preparation step of preparing the processing solution for a semiconductor device by mixing a first chemical solution containing the NH₃, the corrosion inhibitor, and the water with a second chemical solution containing the hydrogen peroxide.

11. A processing solution for a semiconductor device comprising
NH₃, a corrosion inhibitor, and water, wherein
the corrosion inhibitor is at least one selected from the group consisting of 5-methyl-1H-benzotriazole, imidazole, and 5-amino-1H-tetrazole, and
a mass ratio of a content of the NH₃ to a content of the corrosion inhibitor (NH₃/corrosion inhibitor) is 5 to 60.

12. The processing solution for a semiconductor device according to claim 11, further comprising a surfactant.

13. The processing solution for a semiconductor device according to claim 11, further comprising hydrogen peroxide.

14. The processing solution for a semiconductor device according to claim 11, further comprising a chelating agent.

15. The processing solution for a semiconductor device according to claim 13, wherein:
the processing solution for a semiconductor device is a processing solution kit for a semiconductor device including
a first chemical solution containing the NH₃, the corrosion inhibitor, and the water, and
a second chemical solution containing the hydrogen peroxide;
the corrosion inhibitor of the first chemical solution is at least one selected from the group consisting of 5-methyl-1H-benzotriazole, imidazole, and 5-amino-1H-tetrazole; and
a mass ratio of a content of the NH₃ to a content of the corrosion inhibitor of the first chemical solution is 5 to 60.
